(19) United States
(12) Patent Application Publication
(10) Pub. No.: US 2014/0374834 A1
(43) Pub. Date: Dec. 25, 2014

(54) GERMANIUM STRUCTURE, GERMANIUM FIN FIELD EFFECT TRANSISTOR STRUCTURE AND GERMANIUM COMPLEMENTARY METAL-OXIDE-SEMICONDUCTOR TRANSISTOR STRUCTURE

(71) Applicant: National Applied Research Laboratories, Taipei City (TW)

(72) Inventors: Guang-Li Luo, Hsinchu (TW); Chee-Wee Liu, Hsinchu (TW); Shu-Han Hsu, Hsinchu (TW); Chun-Lin Chu, Hsinchu (TW); Chih-Hung Lo, Hsinchu (TW)

(21) Appl. No.: 13/922,354

(22) Filed: Jun. 20, 2013

(51) Int. Cl. H01L 27/092

(52) U.S. Cl. CPC H01L 27/0924
USPC 257/369; 428/450; 428/620; 257/410

(57) ABSTRACT

A germanium (Ge) structure includes a substrate, a Ge layer and at least a Ge spatial structure. The Ge layer is formed on the substrate, and a surface of the Ge layer is a Ge {110} lattice plane. The Ge spatial structure is formed in the Ge layer and includes a top surface and a sidewall surface, wherein the top surface is a Ge {110} lattice plane and the sidewall surface is perpendicular to the top surface. An axis is formed at a junction of the sidewall surface and the top surface, and an extensive direction of the axis is parallel to a Ge [112] lattice vector on the surface of the Ge layer, therefore the sidewall surface is a Ge {111} lattice plane. Because Ge {111} surface channels have very high electron mobility, this Ge spatial structure may be applied for fabricating high-performance Ge semiconductor devices.

### FIELD OF THE INVENTION

The present invention relates to a semiconductor structure, and particularly to a germanium (Ge) structure, a Ge FIN field effect transistor (FINFET) structure and a Ge complementary metal-oxide-semiconductor transistor (CMOS) structure.

### BACKGROUND OF THE INVENTION

The term “crystal material” is a material which has atomics thereof arranged into a periodic lattice structure; the term “single-crystal material” is a material which has entire atomics thereof arranged into the same periodic lattice structure. According to Miller Index (i.e. three dimension indexes of the Cartesian coordinates), a <hkl> lattice vector in the single-crystal material represents a vector running from origin (0,0,0) to a coordinate point (h,k,l), e.g. a <100> lattice vector therein represents a vector running from origin (0,0,0) to coordinate point (1,0,0); a [hkl] lattice vector in the single-crystal material represents a set of equivalent vectors, e.g. a [100] lattice vector therein represents a set of equivalent vectors such as <100>, < 1̅00>, <010>, <0 1̅0>, <001> and <00 1̅>; a (hkl) lattice plane in the single-crystal material represents a plane having a normal vector <hkl>, e.g. a (100) lattice plane therein represents a plane having a normal vector <100>; a {hkl} lattice plane in the single-crystal material represents a set of equivalent planes, e.g. a {100} lattice plane therein represents a set of planes having their respective normal vectors <100>, < 1̅00>, <010>, <0 1̅0>, <001> and <00 1̅>; then the <hkl> lattice vector is perpendicular to the (hkl) lattice plane in the single-crystal material, e.g. the <100> lattice vector is perpendicular to the (100) lattice plane therein.

In the sub-10 nm generation of semiconductor fabricating process, it will be a solution to use a semiconductor material having high carrier mobility such as Ge for the demand of improving the performance of the semiconductor device. In an electric field perpendicular to the surface of single-crystal Ge, a potential well is formed beneath the surface thereof. Due to the quantum confinement effect, the electrons inside single-crystal Ge are redistributed to occupy the lowest energy state in the potential well. The electrons of occupying the lowest energy state have the lowest effective mass while they are moving in {111} lattice plane, therefore a electron-carrier (N-type) semiconductor device, e.g. N-type Ge FETs, has a high carrier mobility by using a Ge {111} lattice plane as a electron channel.

From the foregoing description, an N-type Ge FINFET with its FIN structure having {111} sidewalls can provide very high electrical performance. However, conventional semiconductor fabricating technology can not produce the standard N-type Ge FINFET structure having the Ge {111} lattice plane as the electron channel. Therefore, one of the main aspects of the present invention is to provide the solution of fabricating high performance semiconductor devices.

### SUMMARY OF THE INVENTION

An aspect of the present invention provides a Ge structure. The Ge FINFET structure includes a substrate, a Ge layer and at least a Ge spatial structure. The Ge layer is formed on the substrate, and a surface of the Ge layer is a Ge {110} lattice plane. The Ge spatial structure is formed in the Ge layer and includes a top surface and a sidewall surface, wherein the top surface is a Ge {110} lattice plane and the sidewall surface is perpendicular to the top surface. An axis is formed at a junction of the sidewall surface and the top surface, and an extensive direction of the axis is parallel to a Ge [112] lattice vector on the surface of the Ge layer, therefore the sidewall surface is a Ge {111} lattice plane.

Another aspect of the present invention provides a Ge FINFET structure. The Ge FINFET structure includes a substrate, at least a Ge spatial structure. The substrate has a surface of {110} lattice plane. The Ge spatial structure is formed on the substrate and includes a channel region and an N-type source/drain (S/D) region. The channel region has a top surface of a Ge {110} lattice plane and a sidewall surface of a Ge {111} lattice plane perpendicular to the top surface, wherein an axis is formed at a junction of the sidewall surface and the top surface, and an extension direction of the axis is parallel to a [112] lattice vector on the surface of the substrate. The N-type source/drain (S/D) region is disposed at both sides of the channel.

Another aspect of the present invention provides a Ge CMOS structure. The Ge CMOS structure includes a substrate, a Ge layer, at least a Ge N-type FINFET structure and at least a Ge P-type planar FET structure. The Ge layer is formed on the substrate, and a surface of the Ge layer is a Ge {110} lattice plane. The Ge N-type FINFET structure is formed in the Ge layer and has a first channel region, an N-type source/drain (S/D) region, and a first gate. The channel region has a top surface of a Ge {110} lattice plane and a sidewall surface of a Ge {111} lattice plane perpendicular to the top surface, wherein an axis is formed at a junction of the sidewall surface and the top surface, and an extension direction of the axis is parallel to a [112] lattice vector on the surface of the substrate. The N-type source/drain (S/D) region is disposed at both sides of the first channel region. The first gate is disposed on the first channel region. The Ge P-type planar FET structure is formed in the Ge layer and includes a second channel region, a P-type S/D region and a second gate. The second channel region is formed on the surface of the Ge layer and has a Ge {110} lattice plane. The P-type S/D region is formed in the Ge layer and disposed at both sides of the second channel region. The second gate is formed on the second channel region.

### BRIEF DESCRIPTION OF THE DRAWINGS

The above objects and advantages of the present invention will become more readily apparent to those ordinarily skilled in the art after reviewing the following detailed description and accompanying drawings, in which:

FIGS. 1A˜1C schematically illustrate a Cartesian coordinate graph of lattice vectors and planes in a single-crystal Ge layer;

FIGS. 2A˜2E schematically illustrate a Ge FINFET structure according to a first embodiment of the present invention; and

FIGS. 3A˜3D schematically illustrate a Ge FINFET structure according to a second embodiment of the present invention.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

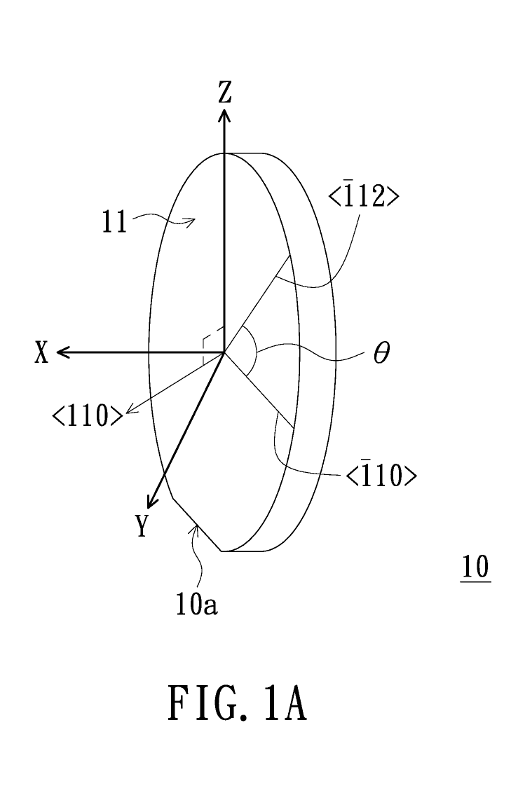

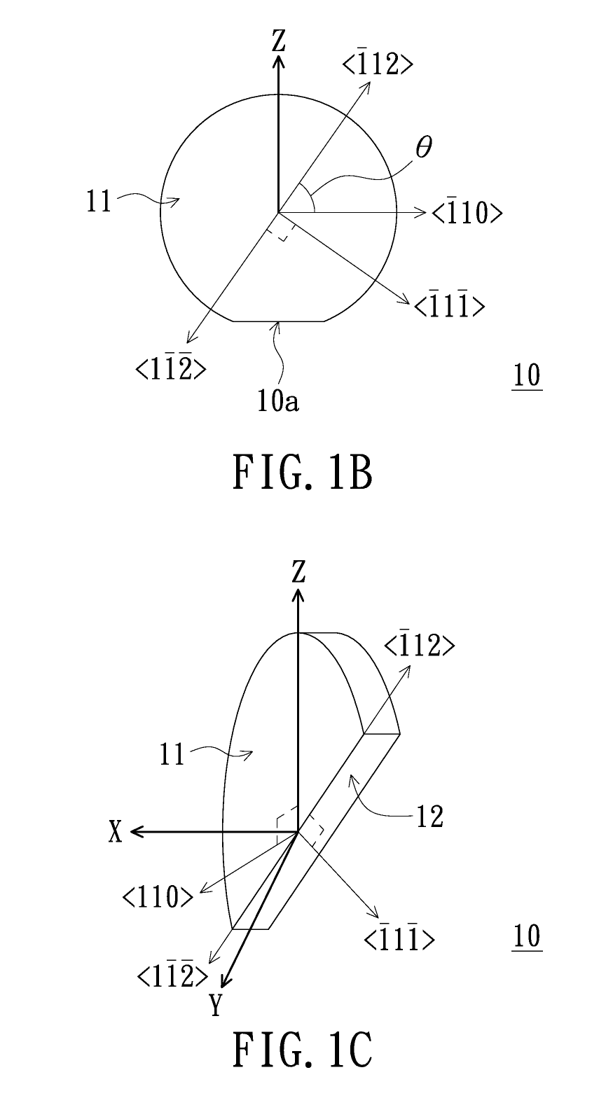

FIGS. 1A˜1C schematically illustrate a Cartesian coordinate graph of lattice vectors and planes in a single-crystal Ge layer.

Firstly, please refer to a three-dimensional Cartesian coordinates graph as shown in FIG. 1A. For a brief description, FIG. 1A illustrates a lateral view of a single-crystal Ge layer 10. The vertical axis is marked as a z-axis (along the <001> lattice vector); the two horizontal axes are marked as an x-axis (along the <100> lattice vector) and a y-axis (along the <010> lattice vector respectively. The single-crystal Ge layer 10 is illustrated as a wafer-like disc, wherein a centre of the single-crystal Ge layer 10 is located at the origin (0,0,0) of the three-dimensional Cartesian coordinates. A surface 11 of the single-crystal Ge layer 10 is a Ge (110) lattice plane. A vertical mark “ [symbol] ” represents that the <110> lattice vector is perpendicular to the surface 11, also the <110> lattice vector is a normal vector of the Ge (110) lattice plane. A flat side surface 10a of the single-crystal Ge layer 10 is a Ge (00 1̅) lattice plane, and a Ge <00 1̅> lattice vector (not shown) is a normal vector of the flat side surface 10a. A Ge < 1̅12> lattice vector on the surface 11 is a lattice vector rotates Θ degree (Θ degree is about 54.7 degree) counter-clockwise from the Ge < 1̅10> lattice vector on the surface 11, and a Ge <1 1̅ 2̅> lattice vector (shown in FIG. 1B) on the surface 11 is a lattice vector rotates π-Θ degree clockwise from the Ge < 1̅10> lattice vector on the surface 11.

Then, please refer to a two-dimensional Cartesian coordinates graph as shown in FIG. 1B. FIG. 1B illustrates a top view of the surface 11 of the single-crystal Ge layer 10. The vertical axis is marked as the z-axis perpendicular to the Ge < 1̅10> lattice vector on the surface 11. A Ge < 1̅1 1̅> lattice vector on the surface 11 is perpendicular to the Ge <112> lattice vector, and the Ge <1 1̅ 2̅> lattice vector is on an opposite direction of the Ge < 1̅12> lattice vector.

Next, please refer to a three-dimensional Cartesian coordinates graph as shown in FIG. 1C. FIG. 1C illustrates a lateral view of a single-crystal Ge layer 10 cut along the Ge < 1̅12> lattice vector and the Ge <1 1̅ 2̅> lattice vector. A cut surface 12 is formed after the single-crystal Ge layer 10 was cut along the Ge < 1̅12> lattice vector and the Ge <1 1̅ 2̅> lattice vector. The Ge < 1̅1 1̅> lattice vector is perpendicular to the cut surface 12, therefore the cut surface 12 is the Ge (111) lattice plane, that is, one of {111} planes.

Please refer to FIG. 1B again. It is noted that due to symmetry of lattice structure, a Ge < 1̅1 2̅> lattice vector (not shown) on the surface 11 is a lattice vector rotates Θ degree (Θ degree is about 54.7 degree) clockwise from the Ge < 1̅10> lattice vector, and a Ge <1 1̅2> lattice vector (not shown) on the surface 11 is a lattice vector rotates π-Θ degree counter-clockwise from the Ge < 1̅10> lattice vector on the surface 11. The Ge <1 1̅2> lattice vector is on an opposite direction of the Ge < 1̅1 2̅> lattice vector. A cut surface (not shown) having Ge ( 1̅11) lattice plane is formed after the single-crystal Ge layer 10 was cut along the Ge < 1̅1 2̅> lattice vector and the Ge <1 1̅2> lattice vector.

From the above description refer to FIG. 1A˜1C, the present invention provides the Ge spatial structure having the vertical surface of a Ge {111} lattice plane by cutting the single-crystal Ge layer along the Ge [112] lattice on the {110} surface of the single-crystal Ge layer. It is worth noting that the Ge [112] lattice vector on the single-crystal Ge layer in the present invention represents a lattice vector within Θ±5 degree counter-clockwise rotation or π-Θ degree clockwise rotation from the [110] lattice vector on the surface of the single-crystalline Ge layer. In details, in the present invention, the term of “the Ge [112] lattice vector on the surface of the Ge layer” represents a lattice vector within 50˜60 degree counter-clockwise rotation or 120˜130 degree clockwise rotation from the Ge [110] lattice vector on the surface of the Ge layer.

The present invention provides an N-type Ge FINFET structure having high electron mobility by using the Ge spatial structure having the vertical surface of a Ge {111} lattice plane.

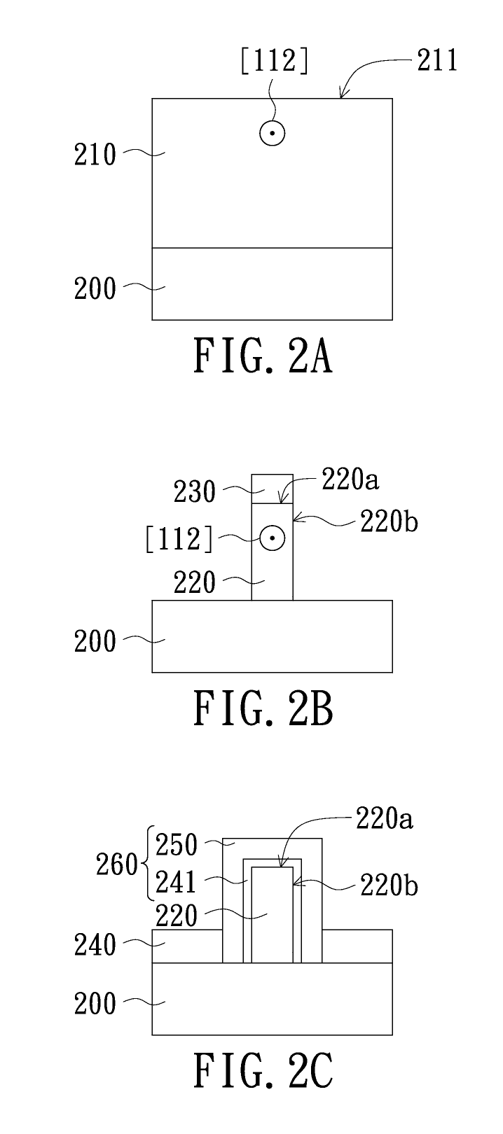

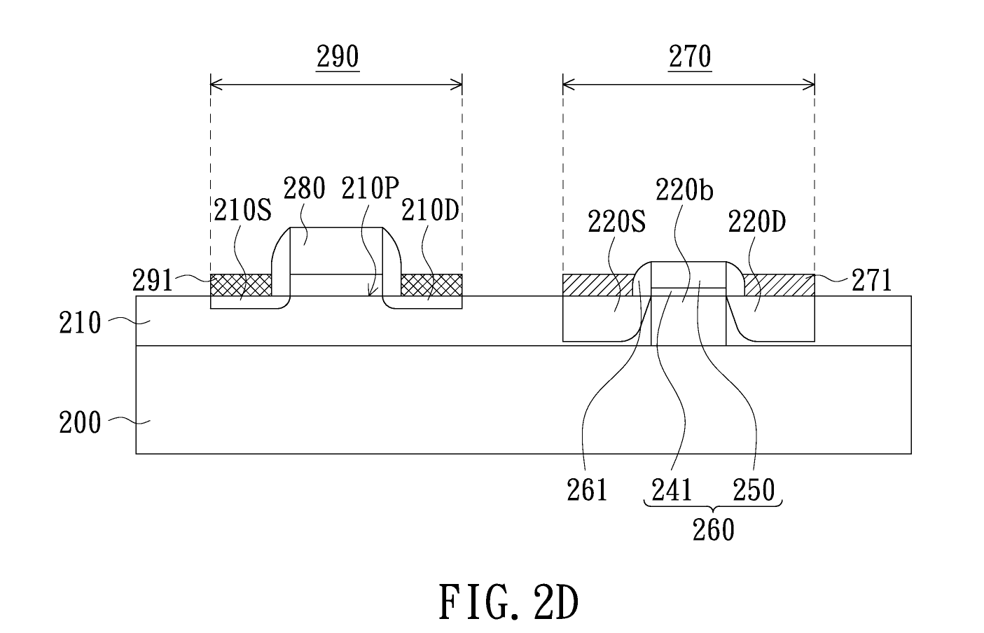

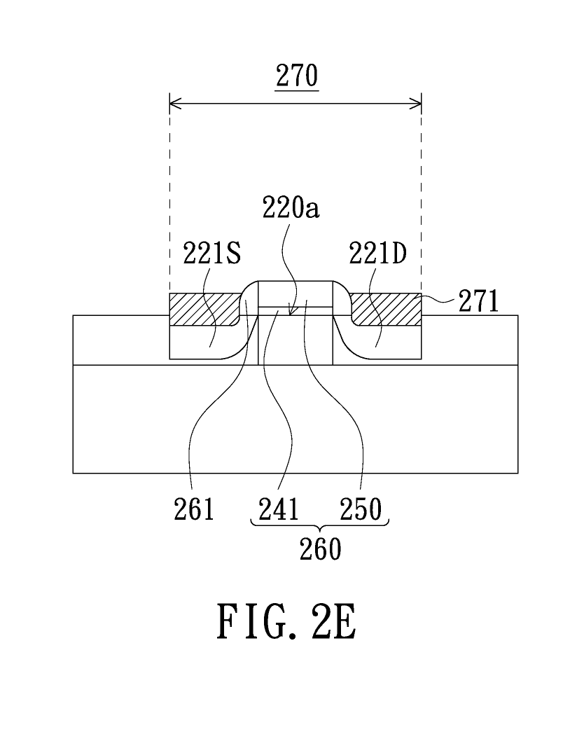

FIGS. 2A˜2E schematically illustrate a Ge FINFET structure according to a first embodiment of the present invention.

Firstly, please refer to a cross-sectional view as shown in FIG. 2A. A Ge layer 210 is formed on a substrate 200, wherein the substrate 200 is a Ge substrate, bulk silicon (Si) substrate, Si on insulator (SOI) substrate, or compound semiconductor substrate (e.g. gallium arsenide), and a surface 211 of the Ge layer 210 is a Ge {110} lattice plane. A mark “⊙” as shown in FIG. 2A˜2B represents a Ge [112] lattice vector perpendicular to the paper. The Ge layer 210 may be formed with different processes such as: growing an epitaxial layer on the substrate to form the Ge layer 210; forming the Ge layer 210 on a buffer layer (not shown) after the buffer layer is formed on the substrate (e.g. Siₓ—Ge_{y} buffer layer), wherein the buffer layer is used for adjusting a lattice mismatch between the Ge layer 210 and the substrate 200 formed with other semiconductor material than Ge, so as to reduce a dislocation formed in the Ge layer; or by performing the smart cut process, which includes steps of: forming the Ge layer 210 on another substrate (not shown); forming an oxide layer (not shown) between the Ge layer 210 and the substrate; cutting the Ge layer 210 with the oxide layer; and fitting the Ge layer 210 with the oxide layer on the substrate 200, the present invention is no limit thereon. On the other hand, the aforesaid dislocation formed in the Ge layer may be eliminated with a rapid thermal annealing process or a cyclic annealing process according to a patent application of Taiwan application NO. 101117652.

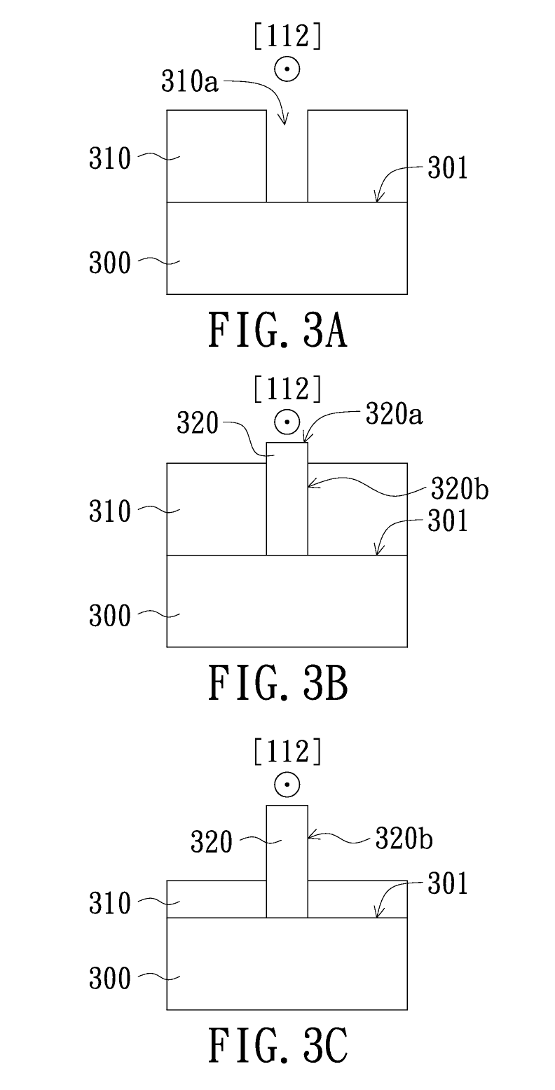

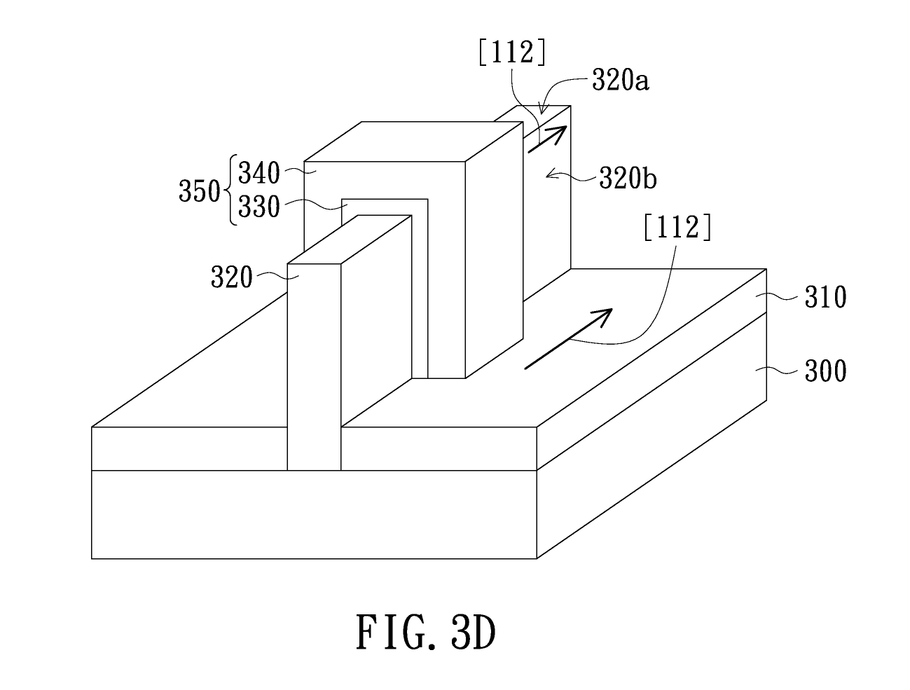

Next, please refer to the cross-sectional view as shown in FIG. 2B. After a mask 230 is formed on the surface 211 according to the Ge [112] lattice vector, a portion of the Ge layer 210 is removed, and then a Ge spatial structure 220 is formed. Optionally, in some embodiment, due to the lattice mismatch between the Ge layer and the substrate formed with other semiconductor material than Ge, a misfit dislocation region is formed at the interface between the Ge layer and the substrate, the misfit dislocation region may be eliminated with an anisotropic etching process according to the patent application (Taiwan application NO. 101117652), the Ge spatial structure may be floated over the substrate, so as a bottom surface (not shown) of the Ge spatial structure is formed. In this embodiment, the Ge spatial structure 220 bonds on the substrate 200, and includes a top surface 220a and a sidewall surface 220b. The top surface 220a is the Ge {110} lattice plane same as the surface 211. An axis (marked with an arrow symbol as shown in FIG. 3D) is formed at a junction of the sidewall surface and the top surface, and an extensive direction of the axis is parallel to the Ge [112] lattice vector, therefore the sidewall 220b surface is a Ge {111} lattice plane.

Next, please refer to the cross-sectional view as shown in FIG. 2C. An insulation structure layer 240 such as silicon oxide is formed on the Ge layer including the Ge spatial structure 220 with a chemical vapor deposition (CVD) process or an atomic layer deposition (ALD) process. Then, a portion of the Ge spatial structure 220 is exposed after the insulation structure layer 240 is partially removed. Then, a gate dielectric layer 241 is formed on a portion of the exposed Ge spatial structure 220 with a high dielectric constant (high k) material such as zirconium dioxide, hafnium oxide or aluminum oxide; a conduction structure 250 is formed on the gate dielectric layer 241 with titanium nitride, aluminum or other conductive material; and a first gate 260 is composed of the gate dielectric layer 241 and the conduction structure 250. The first gate 260 coats a portion of the top surface 220a and sidewall surface 220b. An implantation process is performed with N-type dopant such as phosphorus (P) or arsenic (As), then an electron-carrier (N-type) S/D region is formed in the exposed portion of Ge spatial structure 220 and disposed at both sides of the gate. The Ge spatial structure as shown in FIG. 2C may be applied for fabricating a standard N-type Ge FINFET having a vertical channel surface of Ge {111} lattice plane.

According to the present invention, the Ge spatial structure having the vertical sidewall surface of the Ge {111} lattice plane is easily fabricated on the Ge layer having the surface of the Ge {110} lattice plane and effectively applied for fabricating the high performance N-type Ge FINFET. Moreover, hole carriers have high mobility on the Ge {110} lattice plane, therefore the present invention further provides a hole-carrier (P-type) Ge planar FET structure formed on the surface of the Ge layer.

Next, please refer to the cross-sectional view as shown in FIG. 2D. The Ge layer 210 includes the N-type Ge FINFET structure 270, further includes the P-type Ge planar FET structure 290. The P-type Ge planar FET structure 290 can be completed based on conventional technology; it is not redundantly mentioned herein. A channel 210P is disposed beneath a second gate 280 of the P-type Ge planar FET structure, and a surface of the channel 210P is the Ge {110} lattice plane; the sidewall surface 220b of the vertical channel of the N-type Ge FINFET structure is the Ge {111} lattice plane. The N-type Ge FINFET structure 270 having the vertical channel of Ge {111} lattice plane and the P-type Ge planar FET structure 290 having the channel 210P of Ge {110} lattice plane can be combined to form a complementary metal-oxide-semiconductor (CMOS) FET with excellent electricity performance.

In detail, the N+ source region 220S and drain region 220D are respectively disposed at both sides of the first gate 260 composed of the gate dielectric layer 241 and the conduction structure 250, and moreover, a first stressor layer 271 is disposed above the N+ source 220S and drain region 220D in the N-type Ge FINFET structure 270. The first stressor layer 271 may be formed as following steps. Firstly, a first gate spacer 261 is formed on and around a sidewall of the first gate, and a portion of the Ge spatial structure is exposed. Then, after an N+ implantation process is completed, the N+ source region 220S and drain region 220D are formed in the exposed portion of the Ge spatial structure. And, an epitaxial layer of a N+ doped semiconductor material, which has a lattice constant less than a lattice of Ge such as Si, SiₓGe_{y}, SiGe:C or SiC, is grown on the N+ source region 220S and drain region 220D to form the first stressor layer 271. The first stressor layer can further increase electron-carriers mobility with forming a tensile strain on the channel of the N-type Ge FINFET structure 270. Moreover, in response to different characteristics between electron and hole carriers, the present invention provides a second stressor layer 291 in the P-type Ge planar FET structure 290. The second stressor layer 291 disposed on a P+ source region 210S and a P+ drain region 210D is formed with P+ doped semiconductor material, which has a lattice constant greater than a lattice of Ge such as GeSn. In this embodiment, a stressor type of the first and second stressor layer is formed as a raised type stressor. Optionally, the stressor type of the first or second stressor layer can be formed as an embedded type stressor in some embodiment.

Next, please refer to the cross-sectional view as shown in FIG. 2E. After the first gate spacer 261 is formed on and around the sidewall of the first gate 260 and the portion of the Ge spatial structure is exposed, the exposed portion of the Ge spatial structure is partially removed to allow a height of a top surface of an N+ source 221S and an N+ drain 221D region is lower a height of the top surface 220a. Then, as the above mentioned method of forming the first stressor layer 271 of an embedded type stressor is formed above the N+ source region 221S and drain region 221D in the N-type Ge FINFET structure 270.

FIGS. 3A˜3D schematically illustrate a Ge FINFET structure according to a second embodiment of the present invention.

Firstly, please refer to a cross-sectional view as shown in FIG. 3A. An insulation layer 310 is formed on a substrate 300, wherein the substrate 300 is a Ge substrate, bulk Si substrate, SOI substrate, or compound semiconductor substrate (e.g. gallium arsenide), the present invention is no limit thereon. A surface 301 of the substrate 300 is a {110} lattice plane, and a mark “⊙” as shown in FIG. 3A˜3C represents a [112] lattice vector perpendicular to the paper. After a portion of the insulation layer 310 is removed according to a [112] lattice vector on the surface 301 of the substrate 300, at least an opening 310a is formed.

Next, please refer to the cross-sectional view as shown in FIG. 3B. An epitaxial Ge layer is grown on the substrate with the {110} lattice plane of the surface 301. The epitaxial Ge layer includes at least a Ge spatial structure 320, and the Ge spatial structure 320 is formed in the opening 310a. The Ge spatial structure 320 includes a top surface 320a and a sidewall surface 320b, wherein the top surface is a Ge {110} lattice plane, and the sidewall surface is a {111} lattice plane. Next, please refer to the cross-sectional view as shown in FIG. 3C. After a portion of the insulation layer 310 is back etched, a portion of the sidewall surface 320 is exposed.

Next, please refer to the schematic perspective view of the Ge spatial structure 320 as shown in FIG. 3D. The axis (marked with the arrow symbol) is formed at a junction of the sidewall surface 320b and the top surface 320a, and an extension direction of the axis is parallel to the lattice vector of the substrate, and the sidewall surface 320 is a Ge {111} lattice plane. A gate dielectric layer 330 is formed on a portion of the Ge spatial structure 320. Then, a conduction structure 340 is coated on the gate dielectric layer 320, and a gate 350 is composed of the conduction structure 340 and the gate dielectric layer 330. The Ge spatial structure 320 may be applied for fabricating a Ge FINFET which vertical FIN sidewalls are Ge {111} lattice planes.

From the above description, the Ge FINFET with vertical FIN sidewalls of {111} planes of the present invention can be easily fabricated along [112] lattice vectors on the Ge layers with surfaces of the Ge {110} lattice planes, and can be effectively applied for fabricating semiconductor devices with excellent electrical performance.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A germanium (Ge) structure comprising:
a substrate;
a Ge layer, formed on the substrate, wherein a surface of the Ge layer is a Ge {110} lattice plane; and
at least a Ge spatial structure, formed in the Ge layer and comprising:
a top surface having a Ge {110} lattice plane; and
a sidewall surface perpendicular to the top surface and having a Ge {111} lattice plane, wherein an axis is formed at a junction of the sidewall surface and the top surface, and an extension direction of the axis is parallel to a Ge [112] lattice vector on the surface of the Ge layer.

2. The Ge structure according to claim 1, wherein the substrate is a substrate of silicon (Si), Ge or gallium arsenide, and a surface of the substrate is a {110} lattice plane.

3. The Ge structure according to claim 2, wherein the substrate comprises an oxide layer formed on a surface of the substrate, the oxide layer comprises an opening parallel to a [112] lattice vector on the surface of the substrate, and the Ge spatial structure is formed in the opening.

4. The Ge structure according to claim 1, wherein the Ge [112] lattice vector on the surface of the Ge layer represents a lattice vector within 50˜60 degree counter-clockwise rotation or 120˜130 degree clockwise rotation from a Ge [110] lattice vector on the surface of the Ge layer.

5. A Ge FINFET structure comprising:
a substrate, having a surface of {110} lattice plane; and
at least a Ge spatial structure, formed on the substrate and comprising:
a channel region, having a top surface of a Ge {110} lattice plane and a sidewall surface of a Ge {111} lattice plane substantially perpendicular to the top surface, wherein an axis is formed at a junction of the sidewall surface and the top surface, and an extension direction of the axis is parallel to a [112] lattice vector on the surface of the substrate; and
an N-type source/drain (S/D) region, disposed at both sides of the channel.

6. The Ge FINFET structure according to claim 5, wherein the substrate is a substrate of silicon (Si), Ge or gallium arsenide and comprises a Ge layer formed thereon, a surface of the Ge layer is a Ge {110} lattice plane, and the Ge spatial structure is formed in the Ge layer.

7. The Ge FINFET structure according to claim 5, wherein the substrate comprises an oxide layer formed on a surface of the substrate, the oxide layer comprises an opening parallel to a [112] lattice vector on the surface of the substrate, and the Ge spatial structure is formed in the opening.

8. The Ge FINFET structure according to claim 5, wherein the [112] lattice vector on the surface of the substrate represents a lattice vector within 50˜60 degree counter-clockwise rotation or 120˜130 degree clockwise rotation from a [110] lattice vector on the surface of the substrate.

9. The Ge FINFET structure according to claim 5, further comprising:
at least a dielectric layer, formed on the channel region;
a conduction structure, coated on the dielectric layer, wherein a gate is composed of the conduction structure and the dielectric layer;
a spacer, formed on and around a sidewall of the gate.

10. The Ge FINFET structure according to claim 9, wherein a material of the dielectric layer is selected from zirconium oxide, hafnium oxide or aluminum oxide.

11. The Ge FINFET structure according to claim 9, wherein a material of the conduction structure is titanium nitride or aluminum.

12. The Ge FINFET structure according to claim 5, wherein the Ge spatial structure further comprises a bottom surface formed beneath the top surface and floated over the substrate.

13. The Ge FINFET structure according to claim 5, further comprising a stressor layer disposed on the N-type S/D region, wherein a lattice constant of the stressor layer is less than a lattice constant of the Ge layer.

14. The Ge FINFET structure according to claim 13, wherein a height of a top surface of the N-type S/D region is lower than a height of the top surface.

15. A Ge CMOS structure, comprising:
a substrate; and
a Ge layer formed on the substrate, wherein a surface of the Ge layer is a Ge {110} lattice plane;
at least a Ge N-type FINFET structure, formed in the Ge layer and comprising:
a first channel region, having a top surface of a Ge {110} lattice plane and a sidewall surface of a Ge {111} lattice plane substantially perpendicular to the top surface, wherein an axis is formed at a junction of the sidewall surface and the top surface, an extension direction of the axis is parallel to a [112] lattice vector on the surface of the substrate, and the Ge N-type FINFET structure comprises disposed on a portion of the sidewall surface;
an N-type source/drain (S/D) region, disposed at both sides of the channel; and
a first gate, disposed on the first channel region; and
at least a Ge P-type planar FET structure, formed in the Ge layer and comprising:
a second channel region, formed on the surface of the Ge layer and having a Ge {110} lattice plane;
a P-type S/D region, formed in the Ge layer and disposed at both sides of the second channel region; and
a second gate, formed on the second channel region.

16. The Ge CMOS structure according to claim 15, wherein the substrate is a substrate of silicon (Si), Ge or gallium arsenide, and a surface of the substrate is a {110} lattice plane.

17. The Ge CMOS structure according to claim 15, wherein the substrate comprises an oxide layer formed on a surface of the substrate, the oxide layer comprises an opening parallel to a [112] lattice vector on the surface of the substrate, and the Ge spatial structure is formed in the opening.

18. The Ge CMOS structure according to claim 15, wherein the Ge [112] lattice vector on the surface of the Ge layer represents a lattice vector within 50˜60 degree counter-clockwise rotation or 120˜130 degree clockwise rotation from a Ge [110] lattice vector on the surface of the Ge layer.

19. The Ge CMOS structure according to claim 15, further comprising a first stressor layer disposed on the N-type S/D region, wherein a lattice constant of the stressor layer is less than a lattice constant of the Ge layer.

20. The Ge CMOS structure according to claim 15, further comprises a second stressor layer disposed on the P-type S/D region, wherein a lattice constant of the second stressor layer is greater than a lattice constant of the Ge layer.
